(19) United States
(12) Patent Application Publication
(10) Pub. No.: US 2003/0099092 A1
(43) Pub. Date: May 29, 2003

(54) Joining structure of heat-radiating plate and optoelectronic heat-emitting device

(76) Inventors: Meng-Cheng Huang, Panchiao City (TW); Wayne Hsieh, Sanchung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/993,689

(22) Filed: Nov. 27, 2001

(51) Int. Cl. H05K 7/20

(52) U.S. Cl. 361/707

(57) ABSTRACT

The present invention provides a joining structure of heat-radiating plate and optoelectronic heat-emitting device, which comprises an optoelectronic heat-emitting device, a heat radiator, and a thermal conductive material. The top face of the optoelectronic heat-emitting device is joined with the bottom face of the heat radiator. A receiving space is disposed on the bottom face of the heat radiator. The thermal conductive material is placed in the receiving space. The area of the top face of the optoelectronic heat-emitting device is smaller than that of the receiving space so that the top face of the optoelectronic heat-emitting device can contact the thermal conductive material in the receiving space. The thermal conductive material can melt into liquid to have good fluidity after being uniformly heated to fill up the gap between the heat radiator and the optoelectronic heat-emitting device, thereby effectively helping the optoelectronic heat-emitting device quickly radiate out heat.

### FIELD OF THE INVENTION

The present invention relates to a joining structure of heat-radiating plate and optoelectronic heat-emitting device and, more particularly, to an improved joining structure capable of helping an optoelectronic heat-emitting device quickly radiate out heat so as to enhance the competitive capacity thereof on the market.

### BACKGROUND OF THE INVENTION

Along with continual progress of scientific technology, operational speeds of electronic tools (e.g., host computers, personal digital assistants, etc.) become faster and faster. Heat generated therein becomes more and more accordingly. In order to effectively radiate heat out of the system so that each device therein can operate under permissible temperatures, heat-radiating systems have become indispensable accessories in today's electronic tools.

As shown in FIG. 1, a prior art joining structure of heat-radiating plate and heat-emitting device comprises a heat-radiating device 10, a heat radiator 11, and a thermal conductive paste 12. The heat-emitting device 10 is joined with a plate body 101 (e.g., a motherboard or an integrated circuit board). The thermal conductive paste 12 can be pasted on the top face of the heat-emitting device 10 to glue the heat radiator 11 and the heat-emitting device 10 together.

The thermal conductive paste 12 will solidify at the room temperature, and will melt into liquid after heated. Although the thermal conductive paste 12 has better heat-radiating effect, a retaining tool is generally used instead to join a heat radiator and an electronic heat-emitting device together because the liquid thermal conductive paste 12 will spill around. The joining way of retaining tool has a higher cost, and wastes much space. Moreover, the heat-radiating effect of the heat radiator 11 is deteriorated.

Accordingly, the above heat-radiating plate and heat-emitting device have inconvenience and drawbacks in practical use. The present invention aims to resolve the problems in the prior art.

### SUMMARY OF THE INVENTION

The primary object of the present invention is to provide a joining structure of heat-radiating plate and optoelectronic heat-emitting device, which is capable of enhancing thermal conductive efficiency of an optoelectronic heat-emitting device and a heat radiator so that heat source generated by the optoelectronic heat-emitting device can be effectively discharged out via the heat radiator, thereby letting an optoelectronic tool operate normally under permissible temperatures.

To achieve the above object, the present invention provides a joining structure of heat-radiating plate and optoelectronic heat-emitting device, which comprises an optoelectronic heat-emitting device, a heat radiator, and a thermal conductive material. The top face of the optoelectronic heat-emitting device can be joined with the bottom face of the heat radiator. A receiving space is disposed on the bottom face of the heat radiator. The thermal conductive material can be placed in the receiving space. The thermal conductive material can melt into liquid to have good fluidity after heated, hence effectively enhancing thermal conductive efficiency. Moreover, the binding effect of the optoelectronic heat-emitting device and the heat radiator can be enhanced after the thermal conductive material cools to solidify, hence effectively helping the optoelectronic heat-emitting device quickly radiate out heat.

The various objects and advantages of the present invention will be more readily understood from the following detailed description when read in conjunction with the appended drawing, in which:

### BRIEF DESCRIPTION OF THE DRAWINGS

FIG. 1 is an exploded perspective view of a heat-radiating plate and a heat-emitting device in the prior art;

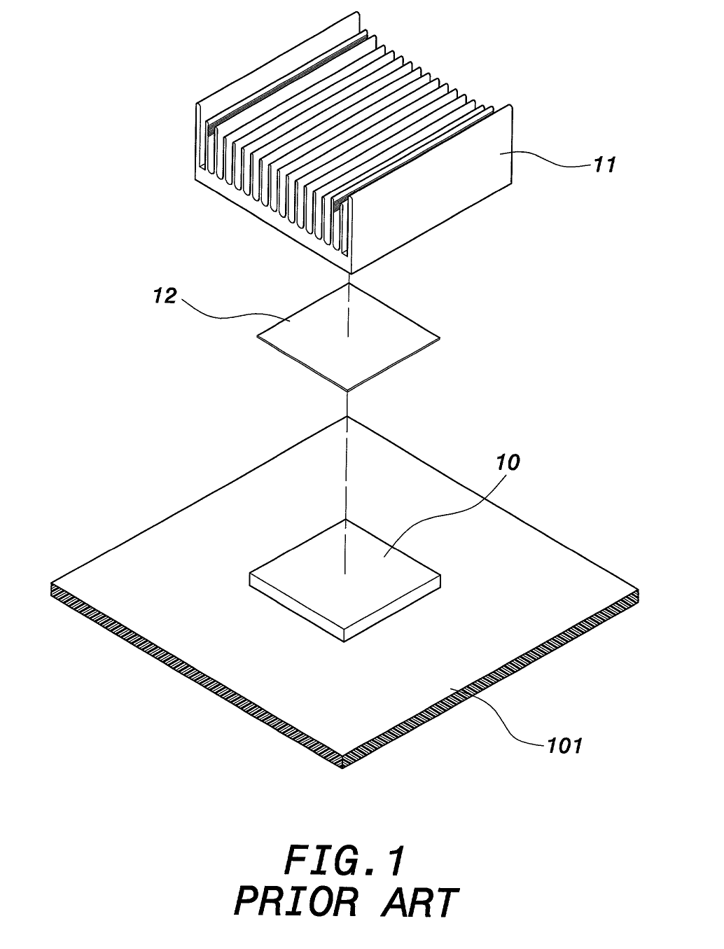

FIG. 2 is an exploded perspective view of the present invention; and

FIG. 3 is a cross-sectional view of the present invention.

### DETAILED DESCRIPTION OF THE PREFERRED EMBODIMENTS

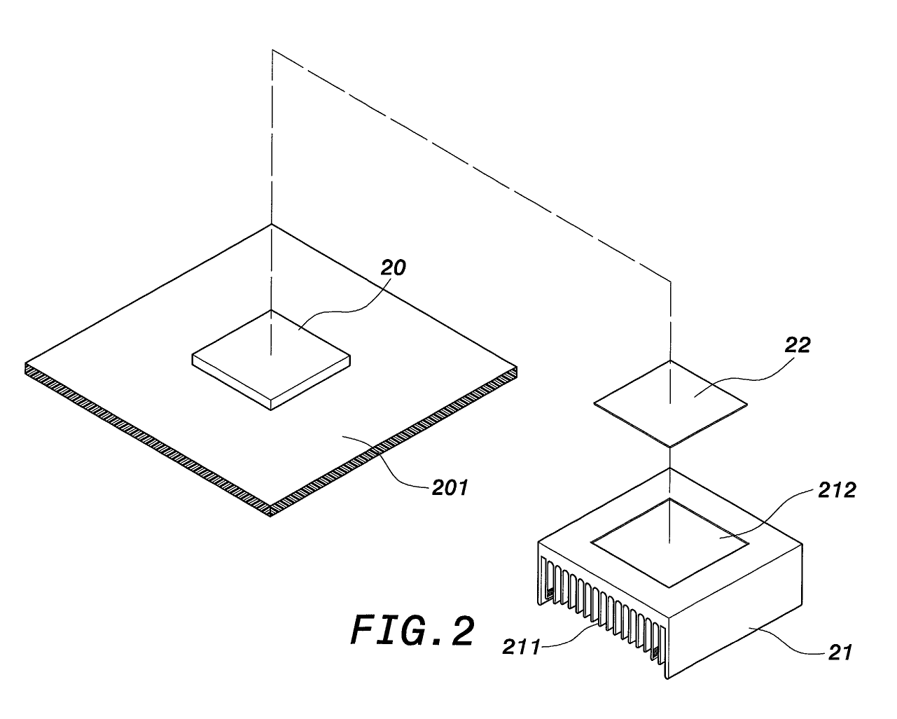

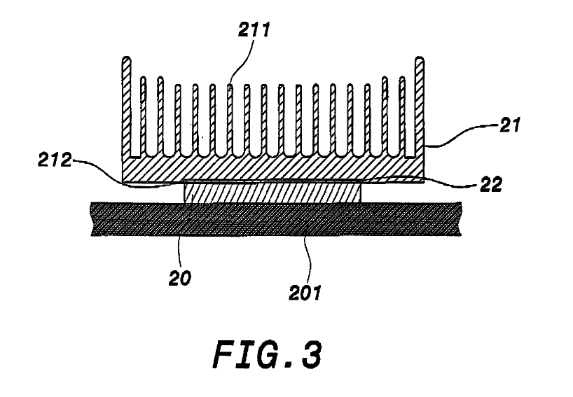

As shown in FIGS. 2 and 3, the present invention relates to a joining structure of heat-radiating plate and optoelectronic heat-emitting device and, more particularly, to an improved joining structure capable of helping an optoelectronic heat-emitting device quickly radiate out heat so as to enhance the competitive capacity thereof on the market. The joining structure of heat-radiating plate and optoelectronic heat-emitting device comprises an optoelectronic heat-emitting device 20, a heat radiator 21, and a thermal conductive material 22.

The optoelectronic heat-emitting device 20 is joined with a plate body 201 (e.g., a motherboard or an integrated circuit board). The top face of the optoelectronic heat-emitting device 20 can be joined with the bottom face of the heat radiator 21. A plurality of fins 211 are formed on the heat radiator 21. The fins 211 can effectively conduct heat source generated by the optoelectronic heat-emitting device 20 to help the optoelectronic heat-emitting device 20 quickly radiate out heat. The above structure and joining way are the same as in the prior art and thus will not be further described.

Also referring to FIGS. 2 and 3, a receiving space 212 is disposed on the bottom face of the heat radiator 21. The thermal conductive material 22 (e.g., thermal conductive wax, thermal conductive glue, or thermal conductive paste) can be placed in the receiving space 212. The area of the top face of the optoelectronic heat-emitting device 20 is smaller than the whole area of the receiving space 212 so that the top face of the optoelectronic heat-emitting device 20 can contact the thermal conductive material 22 in the receiving space 212. The thermal conductive material 22 can melt into liquid to have good fluidity after heated to overspread the top face of the optoelectronic heat-emitting device 20, hence effectively enhancing thermal conductive efficiency and helping the optoelectronic heat-emitting device 20 quickly radiate out heat.

The thermal conductive material 22 can solidify at the room temperature. The binding effect of the optoelectronic heat-emitting device 20 and the heat radiator 21 can be enhanced after the thermal conductive material 22 cools to solidify, thereby increasing the joining strength between the optoelectronic heat-emitting device 20 and the heat radiator 21.

To sum up, the joining structure of heat-radiating plate and optoelectronic heat-emitting device of the present invention has at least the following advantages.

1. The thermal conductive material 22 can melt into liquid having good fluidity to overspread the top face of the optoelectronic heat-emitting device 20, hence effectively enhancing thermal conductive efficiency.

2. The optoelectronic heat-emitting device 20 can be helped to quickly radiate out heat, letting each device in an optoelectronic tool operate normally under permissible temperatures.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A joining structure of heat-radiating plate and optoelectronic heat-emitting device, comprising:
an optoelectronic heat-emitting device;
a heat radiator having a bottom face joined with a top face of said optoelectronic heat-emitting device, a receiving space being disposed on the bottom face of said heat radiator; and
a thermal conductive material received in said receiving space of said heat radiator, said thermal conductive material being capable of melting into liquid to effectively enhance thermal conductive efficiency so as to help said optoelectronic heat-emitting device quickly radiate out heat.

2. The joining structure of heat-radiating plate and optoelectronic heat-emitting device as claimed in claim 1, wherein the area of the top face of said optoelectronic heat-emitting device is smaller than the area of said receiving space.

3. The joining structure of heat-radiating plate and optoelectronic heat-emitting device as claimed in claim 1, wherein said thermal conductive material will solidify at the room temperature.

4. The joining structure of heat-radiating plate and optoelectronic heat-emitting device as claimed in claim 1, wherein said thermal conductive material is thermal conductive wax, thermal conductive glue, or thermal conductive paste.
